(19) United States
(12) Patent Application Publication
(10) Pub. No.: US 2016/0118549 A1
(43) Pub. Date: Apr. 28, 2016

(54) LIGHT EMITTING DEVICE PACKAGE

(71) Applicant: Samsung Display Co. Ltd., Yongin-City (KR)

(72) Inventors: Gi Cherl KIM, Asan-si (KR); Woo Suk SEO, Yongin-si (KR); Seok Hyun NAM, Seoul (KR)

(21) Appl. No.: 14/990,413

(22) Filed: Jan. 7, 2016

Related U.S. Application Data
(62) Division of application No. 14/291,135, filed on May 30, 2014.

(30) Foreign Application Priority Data
Feb. 4, 2014 (KR) 10-2014-0012623

(51) Int. Cl. H01L 33/50; H01L 33/54; H01L 33/62; H01L 33/48

(52) U.S. Cl. CPC H01L 33/50; H01L 33/486; H01L 33/54; H01L 33/62

(57) ABSTRACT

A light emitting device package includes a body, a cavity defined in the body and opened upward, a first electrode positioned in the cavity at least partly and including a first projection portion which projects upward, a second electrode positioned in the cavity at least partly and including a second projection portion which projects upward, a light emitting device positioned on the first projection portion and the second projection portion, and a bump disposed between the light emitting device and the first projection portion and between the light emitting device and the second projection portion, where the light emitting device is electrically connected to the first projection portion and the second projection portion through the bump.

### CROSS REFERENCE TO RELATED APPLICATION

This application is a divisional of U.S. patent application Ser. No. 14/291,135, filed on May 30, 2014, which claims to priority from Korean Patent Application No. 10-2014-0012623, filed on Feb. 4, 2014, and all the benefits accruing therefrom under 35 U.S.C. §119, the disclosure of which is incorporated herein in its entirety by reference.

### BACKGROUND

1. Field

The invention relates to a light emitting device package.

2. Description of the Prior Art

A light emitting device, for example, a light emitting diode, is a kind of semiconductor device that converts electric energy into light, and has been spotlighted as a next-generation light source in replacement of existing light sources such as a fluorescent lamp or an incandescent lamp.

Since the light emitting device generates light using a semiconductor device, it consumes very low power in comparison to the incandescent lamp that generates light through heating of tungsten or the fluorescent lamp that generates light by making ultraviolet (“UV”) light that is generated through high-voltage discharge collision with phosphors. Further, since the light emitting device generates light using an electric potential gap of the semiconductor device, it has a long lifespan, rapid response characteristics, and environment-friendly characteristics in comparison to the existing light sources.

In general, the light emitting device is manufactured in a package form, and with the trend toward high output and high efficiency, a light emitting device package has been applied as a light source of various kinds of products, such as a mobile communication terminal including a personal portable phone or a personal digital assistant (“PDA”), a display device, and an illumination device. Further, with a trend of light, thin, short, and small products as described above, constant efforts have been made to implement a thin light emitting device package with increased light efficiency through improvement of the light emitting device package structure.

### SUMMARY

Accordingly, one subject to be solved by the invention is to provide a light emitting device package which can be implemented by a thin structure and can improve light efficiency.

According to an exemplary embodiment of the invention, there is provided a light emitting device package, which includes a body, a cavity defined in the body and opened upward, a first electrode positioned in the cavity at least partly and including a first projection portion which projects upward, a second electrode positioned in the cavity at least partly and including a second projection portion projecting upward, and a light emitting device positioned on the first projection portion and the second projection portion, a bump disposed between the light emitting device and the first projection portion and between the light emitting device and the second projection portion where the light emitting device is electrically connected to the first projection portion and the second projection portion through the bump.

According to another exemplary embodiment of the invention, there is provided a light emitting device package, which includes a transparent substrate, a first electrode positioned on one surface of the transparent substrate, a second electrode positioned on the one surface of the transparent substrate and spaced apart from the first electrode, a light emitting device positioned on the one surface of the transparent substrate and electrically connected to the first electrode and the second electrode, and a body positioned on the one surface of the transparent substrate and having a cavity provided therein, where the body covers the light emitting device, at least a part of the first electrode, and at least a part of the second electrode.

The details of other embodiments are included in the detailed description and drawings.

According to the exemplary embodiments of the invention, at least the following effects can be achieved.

The light emitting device package can be implemented by a thin structure and the light efficiency can be improved.

The effects according to the invention are not limited to the contents as exemplified above, but further various effects are included in the description.

### BRIEF DESCRIPTION OF THE DRAWINGS

The above and other objects, features and advantages of the invention will be more apparent from the following detailed description taken in conjunction with the accompanying drawings, in which:

FIG. 1 is a plan view of an exemplary embodiment of a light emitting device package according to the invention;

FIG. 2 is a cross-sectional view of the light emitting device package illustrated in FIG. 1;

FIG. 3 is a cross-sectional view illustrating a body of the light emitting device package illustrated in FIG. 2;

FIGS. 4 to 8 are cross-sectional views of an exemplary embodiment of processing operations explaining a method for manufacturing a light emitting device package according to the invention;

FIG. 9 is a view illustrating an exemplary embodiment of the light emitting device package illustrated in FIG. 2;

FIG. 10 is a view illustrating another exemplary embodiment of the light emitting device package illustrated in FIG. 2;

FIG. 11 is a cross-sectional view illustrating an exemplary embodiment of a light emitting device package array according to the invention;

FIG. 12 is a cross-sectional view illustrating an exemplary embodiment of a light emitting device package array according to the invention;

FIG. 13 is a cross-sectional view illustrating another exemplary embodiment of the light emitting device package illustrated in FIG. 2;

FIG. 14 is a cross-sectional view illustrating another exemplary embodiment of the light emitting device package illustrated in FIG. 2;

FIG. 15 is a cross-sectional view illustrating another exemplary embodiment of a light emitting device package array according to the invention;

FIG. 16 is a cross-sectional view illustrating another exemplary embodiment of a light emitting device package array according to the invention;

FIG. 17 is a cross-sectional view of another exemplary embodiment of a light emitting device package according to the invention;

FIGS. 18 to 23 are cross-sectional views of another exemplary embodiment of processing operations explaining a method for manufacturing a light emitting device package according to the invention;

FIG. 24 is a cross-sectional view illustrating an exemplary embodiment of the light emitting device package illustrated in FIG. 17;

FIG. 25 is a cross-sectional view illustrating another exemplary embodiment of the light emitting device package illustrated in FIG. 17;

FIG. 26 is a cross-sectional view illustrating another exemplary embodiment of the light emitting device package illustrated in FIG. 17;

FIG. 27 is a cross-sectional view illustrating another exemplary embodiment of the light emitting device package illustrated in FIG. 17;

FIG. 28 is a cross-sectional view illustrating another exemplary embodiment of the light emitting device package illustrated in FIG. 17;

FIG. 29 is a cross-sectional view illustrating another exemplary embodiment of the light emitting device package illustrated in FIG. 17;

FIG. 30 is a cross-sectional view illustrating another exemplary embodiment of the light emitting device package illustrated in FIG. 17;

FIG. 31 is a cross-sectional view illustrating another exemplary embodiment of the light emitting device package illustrated in FIG. 17;

FIG. 32 is a cross-sectional view illustrating another exemplary embodiment of the light emitting device package illustrated in FIG. 17;

FIG. 33 is a cross-sectional view of a light emitting device package array according to another exemplary embodiment of the invention; and

FIG. 34 is a cross-sectional view of a light emitting device package array according to another exemplary embodiment of the invention.

### DETAILED DESCRIPTION

The exemplary embodiments and features of the invention and methods for achieving the exemplary embodiments and features will be apparent by referring to the exemplary embodiments to be described in detail with reference to the accompanying drawings. However, the invention is not limited to the exemplary embodiments disclosed hereinafter, but can be implemented in diverse forms. The matters defined in the description, such as the detailed construction and elements, are nothing but specific details provided to assist those of ordinary skill in the art in a comprehensive understanding of the invention, and the invention is only defined within the scope of the appended claims. In the drawings, sizes and relative sizes of layers and areas may be exaggerated for clarity in explanation.

The term “on” that is used to designate that an element or layer is on another element or layer includes both a case where an element or layer is located directly on another element or layer and a case where an element or layer is located on another element or layer via still another element or layer. Further, the term “below”, “beneath”, “lower”, or “under” that is used to designate that an element or layer is below, beneath, lower, or under another element or layer includes both a case where an element or layer is located directly below, beneath, lower, or under another element or layer and a case where an element or layer is located below, beneath, lower, or under another element or layer via still another element or layer.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. In the following description of the invention, the terms used are for explaining embodiments of the invention, but do not limit the scope of the invention. In the description, a singular expression may include a plural expression unless specially described. The term “comprises” and/or “comprising” used in the description means that one or more other components, steps, operation and/or existence or addition of elements are not excluded in addition to the described components, steps, operation and/or elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term, “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

Hereinafter, embodiments of the invention will be described with reference to the accompanying drawings.

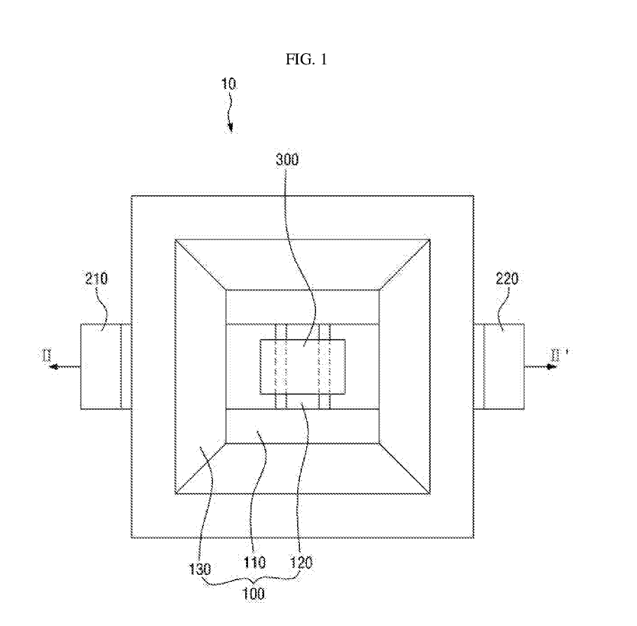

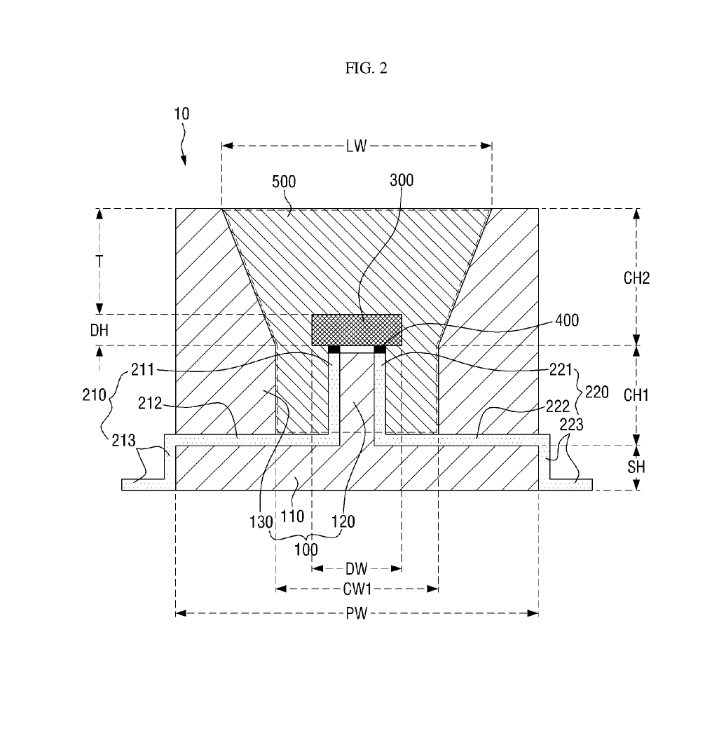

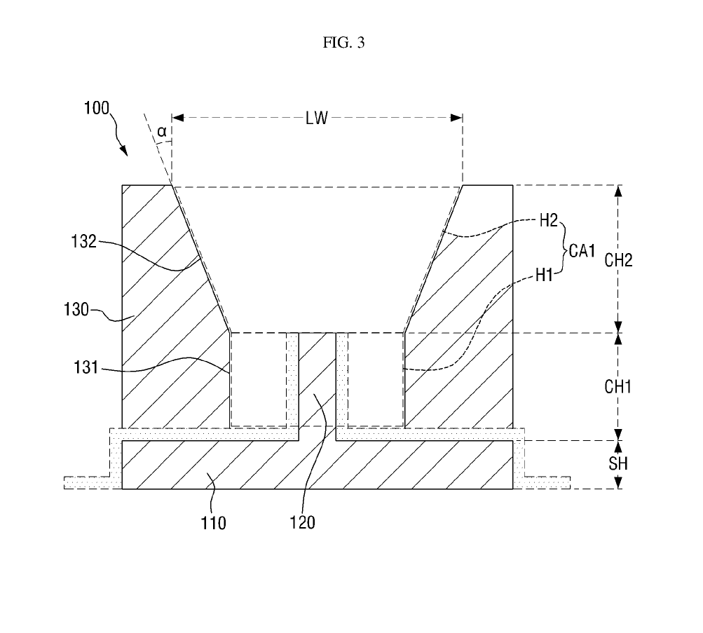

FIG. 1 is a plan view of a light emitting device package according to an exemplary embodiment of the invention, and FIG. 2 is a cross-sectional view of the light emitting device package of FIG. 1, taken along line II-II′ in FIG. 1. FIG. 3 is a cross-sectional view illustrating a body of the light emitting device package illustrated in FIG. 2.

Referring to FIGS. 1 to 3, a light emitting device package 10 according to an exemplary embodiment of the invention may include a body 100, a first electrode 210, a second electrode 220, a light emitting device 300, a bump 400, and an encapsulation portion 500.

The body 100 may include polymer including polyphthalamide (“PPA”) and liquid crystal polymer (“LCP”), which are used as general package materials. Further, the body 100 may include white molding compound having opacity or high light reflectivity. The white molding compound reflects light that is emitted from the light emitting device 300, and increases the quantity of light that is emitted upward. In an exemplary embodiment, the white molding compound may include high heat resistant thermosetting resin or silicon resin, for example. In an exemplary embodiment, the thermoplastic resin may further include at least one of a white pigment, a filler, a curing agent, a release agent, an antioxidant, and an adhesive force improvement agent, for example.

In the illustrated exemplary embodiment in FIG. 1, the upper surface of the body 100 may be in a rectangular shape, but is not limited thereto. Depending on the use purpose and design of the light emitting device 300, the upper surface of the body 100 may have various shapes, such as a triangle, a polygon, and a circle.

The body 100 may include a base portion 110 having a predetermined thickness SH, a support portion 120 projecting upward from the base portion 110, and a side portion 130 positioned on the circumference of the base portion 110 to surround the support portion 120. In an exemplary embodiment, the base portion 110, the support portion 120, and the side portion 130 may be provided through the same process, and the base portion 110 and the support portion 120 may be provided in a unitary body.

A cavity CA1 having an upper opening, a side surface, and a bottom surface may be defined in the body 100. More particularly, an upper surface of the base portion 110 may provide a bottom surface of the cavity CAL and an inner surface of the side portion 130 may provide side surfaces 131 and 132 of the cavity CA1. In other words, the upper surface of the base portion 110 and the inner surface of the side portion 130 may define the cavity CA1. The support portion 120 is positioned in the cavity CAL and may be provided to project upward from the base portion 110.

When the body 100 includes a material having high light reflectivity, the side surfaces 131 and 132 of the cavity CA1 may function as reflective surfaces that reflect light emitted from the light emitting device 300. That is, the side surfaces 131 and 132 of the cavity CA1 may be reflective surfaces. However, in another exemplary embodiment, it is also possible to provide the reflective surfaces by coating or plating a material having superior light reflectivity on the side surfaces 131 and 132 of the cavity CA1.

The upper opening of the cavity CA1 may provide a light emission region. That is, the light emitted from the light emitting device 300 is provided to an outside of the light emitting device package 10 through the upper opening of the cavity CA1. In an exemplary embodiment, the width of the upper opening of the cavity CA1 taken along a horizontal direction in a plan view may be about 200 micrometer (μm) to about 500 μm. Further, in an exemplary embodiment, the width of the upper opening of the cavity CA1 may be about 200 μm to about 400 μm.

The shape of the cavity CAL as seen from an upper side thereof, may be a rectangle as illustrated in FIG. 1, but is not limited thereto. Depending on the use purpose and design of the light emitting device 300, the cavity CA1 may have various shapes, such as a triangle, a polygon, and a circle.

A first groove H1 and a second groove H2 may be defined in the cavity CAL and the first groove H1 may be defined below a lower opening of the second groove H2.

The first groove H1 may have a first depth CH1, and at least one side surface 131 of the first groove H1 may be substantially perpendicular to any one of an upper surface of the base portion 110, an upper surface of the body 100, and the upper opening of the cavity CA1. Further, all side surfaces of the first groove H1 may be substantially perpendicular to the upper surface of the base portion 110, and in this case, the cross section of the first groove H1 may be in a rectangular shape, but is not limited thereto. In another exemplary embodiment, at least one side surface 131 of the first groove H1 may be inclined with reference to the upper surface of the base portion 110. The width CW1 of the first groove H1 may be set enough to accommodate a first projection portion 211, a second projection portion 221, and the support portion 120. The width CW1 of the first groove H1 may be larger than the sum of the widths of the first projection portion 211, the second projection portion 221, and the support portion 120. Further, the width CW1 of the first groove H1 may be smaller than the width LW of the upper opening of the cavity CA1. In an exemplary embodiment, the width CW1 of the first groove H1 may be about 150 μm to about 400 μm or about 150 μm to about 350 μm, but is not limited thereto.

The second groove H2 may have a second depth CH2, and at least one side surface 132 of the second groove H2 may be inclined at a predetermined angle α with reference to the upper surface of the body 100 or the upper opening of the cavity CA1. In an exemplary embodiment, the predetermined angle α may be equal to or larger than 5 degrees and equal to or smaller than 45 degrees, or may be equal to or larger than 5 degrees and equal to or smaller than 15 degrees. The width of the second groove H2 may be increased as going to the upper opening thereof, and the cross section thereof may be in a reverse tapered shape in which the width is increased as going to the upper part thereof, but is not limited thereto. That is, the second groove H2 is not limited thereto, and may have various other shapes.

According to the illustrated exemplary embodiment, since the first groove H1 having a relatively small width and the second groove H2 having a width that is increased as going to the upper opening thereof are defined in the cavity CA1, thereby the light reflection efficiency can be improved.

More specifically, if the inclined side surface 132 is extended to the upper surface of the base portion 110 under the assumption that the width LW of the upper opening of the cavity CA1 has a substantially small value, it becomes difficult to secure the inclination angle α. In particular, when the width LW of the upper opening of the cavity CA1 is small, for example, about 200 μm to about 500 μm, the inclination angel a becomes close to 0 degree. In other words, the angle that is provided by the side surface 132 and the upper surface of the base portion 110 becomes close to right angles. Accordingly, it becomes difficult to secure the inclination angle α for guiding the light emitted from the light emitting device 300 upward. In contrast, in the illustrated exemplary embodiment, the inclined side surface 132 is spaced apart from the upper surface of the base portion 110 by the depth CH1 of the first groove H1, and thus it becomes possible to sufficiently secure the inclination angle α for guiding the light emitted from the light emitting device 300 upward in comparison to a case where the inclined side surface 132 comes in contact with the upper surface of the base portion 110. Accordingly, even when the width LW of the upper opening of the cavity CA1 is set to be small, for example, about 200 μm to about 500 μm, the quantity of light that is emitted to an outside can be increased, and the light efficiency can be improved. That is, according to the illustrated exemplary embodiment, it becomes possible to provide the thin light emitting device package 10 with improved light efficiency.

At least parts of the first electrode 210 and the second electrode 220 may be arranged in the cavity CA1.

In an exemplary embodiment, the first electrode 210 and the second electrode 220 may include a metal material having electrical conductivity, for example, at least one of titanium (Ti), copper (Cu), nickel (Ni), gold (Au), chrome (Cr), tantalum (Ta), platinum (Pt), tin (Sn), silver (Ag), phosphorus (P) and any combinations thereof, for example. Further, the first electrode 210 and the second electrode 220 may have a single layer structure or a multilayer structure.

The first electrode 210 may include a first projection portion 211 projecting upward, a first contact portion 213 exposed to an outside of the body 100, and a first connection portion 212 connecting the first projection portion 211 and the first contact portion 213 to each other. The first projection portion 211 may contact the light emitting device 300 to support the light emitting device 300 which will be described later. The first contact portion 213 may contact an external circuit (e.g., contact terminal of a circuit board), and an end part thereof may project far from an outer surface of the body 100. As illustrated in the drawing, the first contact portion 213 may be in an “L” shape, but is not limited thereto. The first connection portion 212 is a portion electrically connecting the first projection portion 211 and the first contact portion 213 to each other. The first projection portion 211, the first connection portion 212, and the first contact portion 213 may be provided in a unitary body through bending of a bar-shaped electrode, but are not limited thereto.

In the same manner as the first electrode 210, the second electrode 220 may include a second projection portion 221 projecting upward, a second contact portion 223 exposed to an outside of the body 100, and a second connection portion 222 connecting the second projection portion 221 and the second contact portion 223 to each other. The second projection portion 221 is a portion contacting the light emitting device 300 to support the light emitting device 300 which will be described later. The second contact portion 223 is a portion contacting an external circuit (e.g., contact terminal of a circuit board), and an end part thereof may project far from an outer surface of the body 100. In an illustrated exemplary embodiment, the second contact portion 223 may be in an “L” shape, but is not limited thereto. The second connection portion 222 is a portion electrically connecting the second projection portion 221 and the second contact portion 223 to each other. The second projection portion 221, the second connection portion 222, and the second contact portion 223 may be provided in a unitary body through bending of a bar-shaped electrode, but are not limited thereto.

The first projection portion 211 and the second projection portion 221 may be positioned in the cavity CAL and may be spaced apart from each other. The support portion 120 may be positioned between the first projection portion 211 and the second projection portion 221. Parts of the first connection portion 212 and the second connection portion 222 may be positioned in the cavity CA1. That is, as seen from an upper side of the cavity CAL the parts of the first connection portion 212 and the second connection portion 222 may be exposed through the cavity CA1.

In an exemplary embodiment, the length of the first projection portion 211 or the second projection portion 221 that is positioned in the cavity CA1 may be substantially equal to the depth CH1 of the first groove H1. Here, the length of the first projection portion 211 refers to the length measured from the upper surface of the base portion 110 to the upper surface of the first projection portion 211, and in the same manner, the length of the second projection portion 221 refers to the length measured from the upper surface of the base portion 110 to the upper surface of the second projection portion 221. In other words, the upper surface of the first projection portion 211 or the upper surface of the second projection portion 221 may be positioned on the same horizontal plane as a boundary portion of the first groove H1 and the second groove H2.

In an exemplary embodiment, the length of the first projection portion 211 or the second projection portion 221 may be larger than the depth CH1 of the first groove H1. In other words, the upper surface of the first projection portion 211 or the upper surface of the second projection portion 221 may be positioned in the second groove H2. That is, the length of the first projection portion 211 or the length of the second projection portion 221 may be appropriately changed within the limit in which the light emitting device 300 can be positioned in the second groove H2.

In an exemplary embodiment, the first projection portion 211 and the second projection portion 221 may be spaced apart from at least one side surface 131 of the first groove H1. In an exemplary embodiment, a gap CP between the side surface 131 of the first groove H1 and the first projection portion 211 or the second projection portion 221 may be equal to or larger than about 25 μm, but is not limited thereto. That is, in exemplary embodiments, the gap CP between the side surface 131 of the first groove H1 and the first projection portion 211 or the second projection portion 221 may be equal to or smaller than 25 μm, and any one of the first projection portion 211 and the second projection portion 221 may contact the side surface 131 of the first groove H1.

Parts of the first connection portion 212 and the second connection portion 223 may be arranged on the bottom surface of the cavity CAL that is, on the upper surface of the base portion 110, and the remaining parts may be arranged between the side portion 130 and the base portion 110.

The first contact portion 213 and the second contact portion 223 may be positioned outside the body 100. The lower surfaces of the first contact portion 213 and the second contact portion 223 may be arranged on the same horizontal plane as the lower surface of the body 100 or the lower surface of the base portion 110 to facilitate the mounting thereof on the circuit board, but are not limited thereto. That is, in another exemplary embodiment, the lower surfaces of the first contact portion 213 and the second contact portion 223 may be positioned on the upper or lower part of the body 100 rather than the lower surface of the body 100.

The light emitting device 300 may be mounted on the first projection portion 211 and the second projection portion 221. The light emitting device 300 may have so-called volume emitting characteristics in which light is emitted from the whole surface of the light emitting device 300. In an exemplary embodiment, the light emitting device 300 may be a light emitting diode (“LED”), but is not limited thereto. In an exemplary embodiment, the light emitting device 300 may be an LED that emits color light, such as a red LED, a green LED, or a blue LED. Further, the light emitting device 300 may be an LED that emits ultraviolet (“UV”) light. The width DW of the light emitting device 300 may be smaller than the width LW of the upper opening of the cavity CA1, and in an exemplary embodiment, the width DW of the light emitting device 300 may be about 150 μm to about 350 μm, and the thickness DH of the light emitting device 300 may be about 50 μm to 200 μm, but are not limited thereto.

The light emitting device 300 may be electrically connected to the first contact portion 213 and the second contact portion 223 through the medium of a bump 400, such as a solder bump. That is, in an exemplary embodiment, the light emitting device 300 may be bonded onto the first projection portion 211 and the second projection portion 221 in a flip method, and thus a separate wire and a bonding area of such a wire are not necessary. Accordingly, a gap distance between the side surfaces 131 and 132 of the cavity CA1 and the light emitting device 300 can be reduced to finally decrease the size of the body 100, and thus a thin light emitting device package can be provided. Further, since the wire bonding area is not necessary in the body 100 having the same size, a space for mounting a light emitting device can be extended, and thus a light emitting device having a larger size can be mounted. As a result, a high-efficiency light emitting device package can be provided in a space having the same size.

The light emitting device 300 may be positioned in the second groove H2, and in an exemplary embodiment, a whole portion of the light emitting device 300 may be positioned in the second groove H2. That is, the light emitting device 300 may be supported by the first projection portion 211 and the second projection portion 221, and arranged adjacent to the upper opening of the cavity CA1. The light that is emitted from the light emitting device 300 is output through the upper surface and the side surface of the light emitting device 300, and a part of the emitted light is reflected by the side surfaces 131 and 132 of the cavity CA1. Accordingly, when the light emitting device 300 is positioned on the bottom surface of the cavity CA1 or the upper surface of the base portion 110, there is a high possibility that the light emitted through the side surface of the light emitting device 300 is repeatedly reflected in the cavity CA1, thereby the emitted light is finally lost.

However, according to the invention, since the light emitting device 300 is supported by the first projection portion 211 and the second projection portion 221 to be arranged adjacent to the upper opening of the cavity CA1, there is a low possibility that the light emitted through the side surface of the light emitting device 300 is repeatedly reflected by the side surfaces 131 and 132 of the cavity CA1 and finally lost. In other words, a part of the light emitted from the side surface of the light emitting device 300 may be directly output to the upper opening of the cavity CA1, and there is a high possibility that a part of the light emitted from the side surface of the light emitting device 300 is reflected by the side surface 132 of the cavity CA1 having an inclination to guide the light to the relatively upper opening of the cavity CA1. Accordingly, the quantity of light that is directly emitted to an outside without separate reflection and the quantity of light that is emitted to the outside through reflection can be increased to heighten the light efficiency.

The encapsulation portion 500 may fill in the cavity CA1 to encapsulate the light emitting device 300. In an exemplary embodiment, the encapsulation portion 500 may include a light-permeable material, for example, light-permeable resin, such as epoxy, silicon, urethane, oxetane, or acryl. In an exemplary embodiment, the encapsulation portion 500 may further include a wavelength conversion material that converts a part of the light emitted from the light emitting device 300 into light having a different wavelength through excitation of the part of the light such as phosphors. In an exemplary embodiment, phosphors may include at least one of a red phosphor, a green phosphor, and a yellow phosphor, and may include at least one of Yttrium aluminum garnet (“YAG”), terbium aluminum garnet (“TAG”), silicate, nitride, and oxynitride series material, but is not limited thereto.

The upper surface of the encapsulation portion 500 may be in a flat shape, and the thickness of the encapsulation portion 500 measured along a vertical direction in a cross section may be substantially equal to the sum of the depth CH1 of the first groove H1 and the depth CH2 of the second groove H2, but is not limited thereto.

The height T measured from the upper surface of the light emitting device 300 to the upper opening of the cavity CA1 may be about 1 μm to about 130 μm, and in an exemplary embodiment, the height T may be about 50 μm to about 130 μm. Further, when the upper surface of the encapsulation portion 500 is in the flat shape, the height T measured from the upper surface of the light emitting device 300 to the upper surface of the encapsulation portion 500 may be about 1 μm to about 130 μm, and in an exemplary embodiment, the height T may be about 50 μm to about 130 μm. That is, according to the invention, the moving path of the light which is emitted from the light emitting device 300 and passes through the encapsulation portion 500 can be shortened, and thus the light efficiency can be improved.

When the light emitting device 300 is wire-bonded, light is reflected by the wire, and thus a light loss occurs. Further, due to the thickness of the wire itself, the thickness of a solder ball used for wire bonding, and the elasticity of the wire itself, there is a limit in reducing the height between the upper surface of the light emitting device 300 and the upper surface of the encapsulation portion 500. Accordingly, there is a limit in reducing the path of the light which is emitted from the light emitting device 300 and passes through the encapsulation portion 500, and thus it is difficult to improve the light efficiency.

In contrast, according to the invention, the distance between the upper surface of the light emitting device 300 and the upper surface of the encapsulation portion 500 can be reduced, and thus the moving path of the light that passes through the encapsulation portion 500 can be shortened to improve the light efficiency. Further, since the inclination angle α of the side surface 132 of the cavity CA1 can be sufficiently secured, the quantity of light that is guided to the upper opening of the cavity CA1 can be increased. In addition, since the inclination angle α of the side surface 132 of the cavity CA1 is sufficiently secured and the distance between the upper surface of the light emitting device 300 and the upper surface of the encapsulation portion 500 is reduced, the quantity of light component, which is totally reflected from the surface of the encapsulation portion 500 and is re-incident to the inside of the cavity CA1, of the light, which is reflected by the side surface 132 and is provided to the upper opening of the cavity CA1, can be reduced, and thus the light efficiency can be further improved.

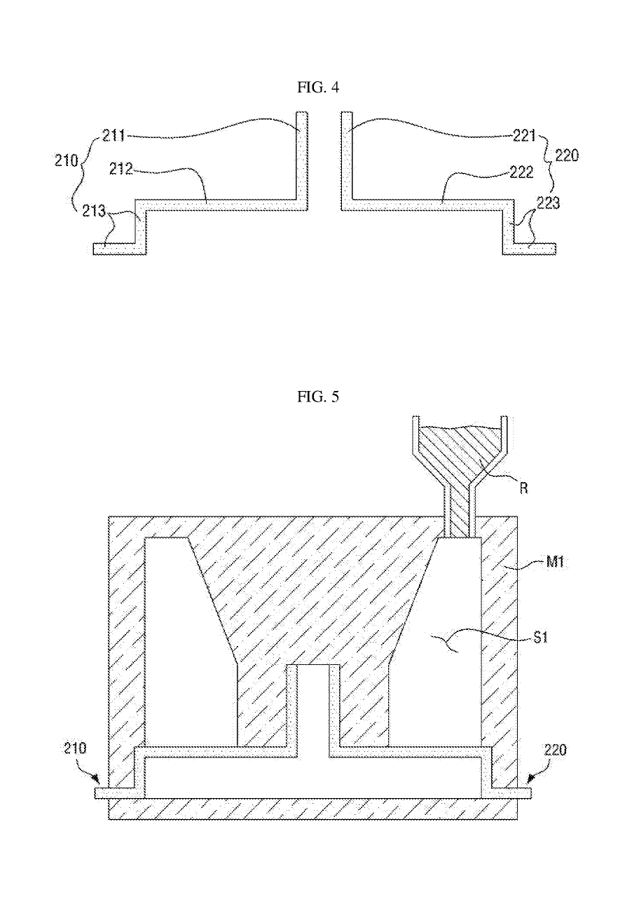

FIGS. 4 to 8 are cross-sectional views of processing operations explaining a method for manufacturing a light emitting device package according to an exemplary embodiment of the invention.

Referring to FIGS. 4 to 8, a first electrode 210 and a second electrode 220, which are separated from each other as shown in FIG. 4, are first prepared. The first electrode 210 may include a first projection portion 211, a first contact portion 213, and a first connection portion 212 connecting the first projection portion 211 and the first contact portion 213 to each other, and may be provided through bending and press working. In the same manner, the second electrode 220 may include a second projection portion 221, a second contact portion 223, and a second connection portion 222 connecting the second projection portion 221 and the second contact portion 223 to each other, and may be provided through bending and press working.

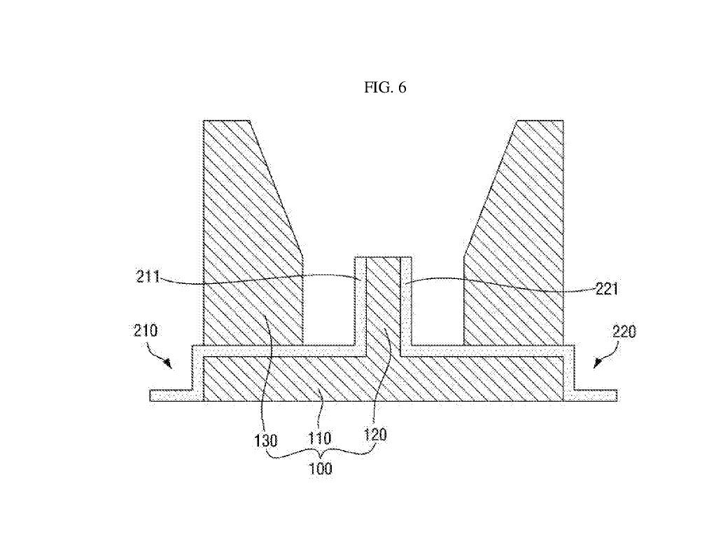

Hereinafter, as illustrated in FIG. 5, the first electrode 210 and the second electrode 220 are fixed in a mold M1 in which a space 51 having a shape that corresponds to the base portion 110, a support portion 120, and a side portion 130 is defined. Further, by injecting resin R into the mold M1, as illustrated in FIG. 6, the body 100 is manufactured, in which the base portion 110, the support portion 120 positioned between the first projection portion 211 and the second projection portion 221, and the side portion 130 are provided in a unitary body. In an exemplary embodiment, the resin R may be polymer including PPA and LCP, which are used as general package materials. In an exemplary embodiment, the resin R may include white molding compound having opacity or high light reflectivity. In the exemplary embodiment, the white molding compound may include high heat resistant thermosetting resin or silicon resin, for example. In the exemplary embodiment, the thermoplastic resin may further include a white pigment, a filler, a curing agent, a release agent, an antioxidant, or an adhesive force improvement agent, for example.

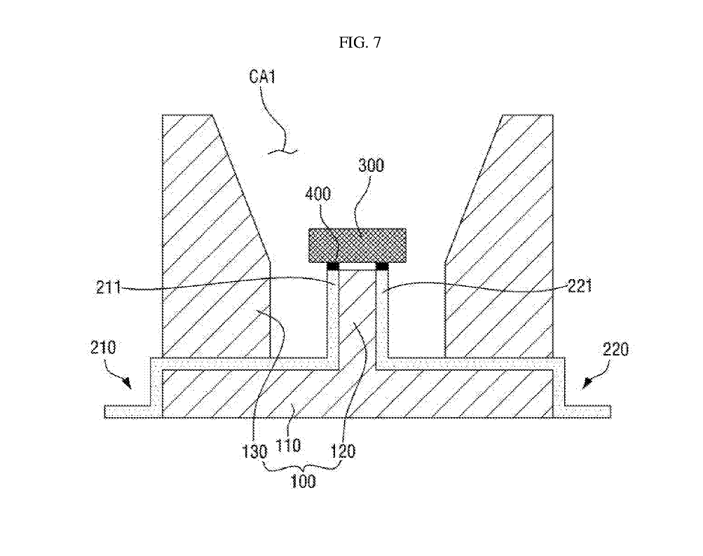

Next, as illustrated in FIG. 7, a light emitting device 300 is connected to the first projection portion 211 and the second projection portion 221 through the medium of a bump 400. That is, in an exemplary embodiment, the light emitting device 300 is flip-chip-bonded onto the first projection portion 211 and the second projection portion 221. Further, as illustrated in FIG. 8, an encapsulation portion 500 is provided in a cavity CA1 to fill in the cavity CA1 and to cover the light emitting device 300. In an exemplary embodiment, the encapsulation portion 500 may include a light-permeable material, for example, light-permeable resin, such as epoxy, silicon, urethane, oxetane, or acryl, and include a wavelength conversion material, for example, at least one kind of phosphor.

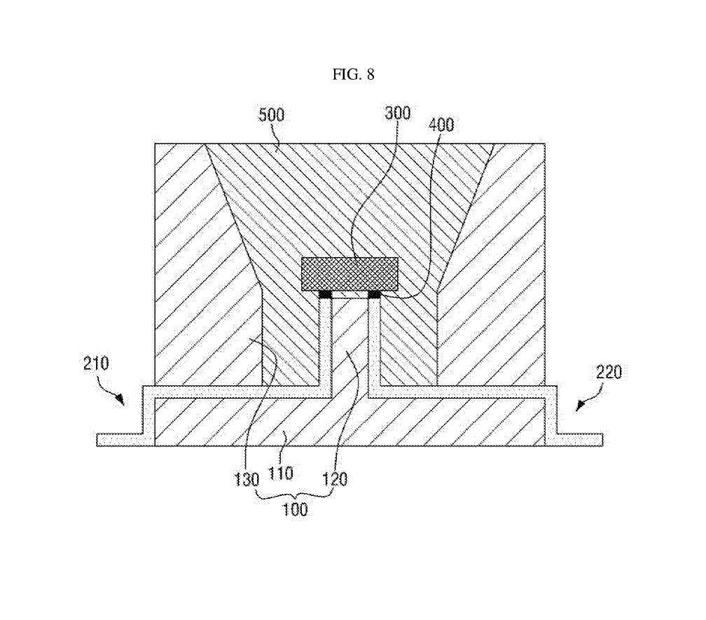

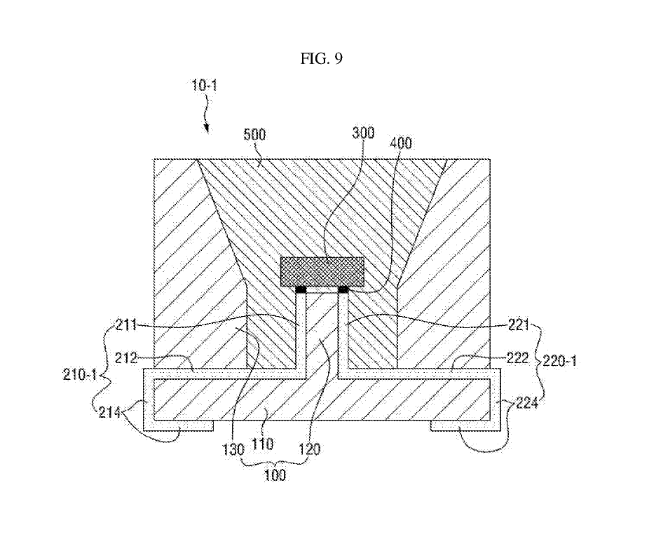

FIG. 9 is a view illustrating an exemplary embodiment of the light emitting device package illustrated in FIG. 2. In the illustrated exemplary embodiment, a light emitting device package 10-1 includes a first electrode 210-1 and a second electrode 220-1 having different structures from those of the light emitting device package 10 illustrated in FIG. 2. Other configurations are the same as those as described above with reference to FIGS. 1 to 8, and the duplicate explanation thereof will be omitted for convenience.

In the illustrated exemplary embodiment, end parts of the first electrode 210-1 and the second electrode 220-1 included in the light emitting device package 10-1 may contact the lower part of the base portion 110. That is, a first contact portion 214 of the first electrode 210-1 may have a structure that extends from one side surface to a lower surface of the base portion 110. In the same manner, the second connection portion 224 may have a structure that extends from the other side surface to the lower surface of the base portion 110, and thus the width of the light emitting device package 10-1 can be reduced.

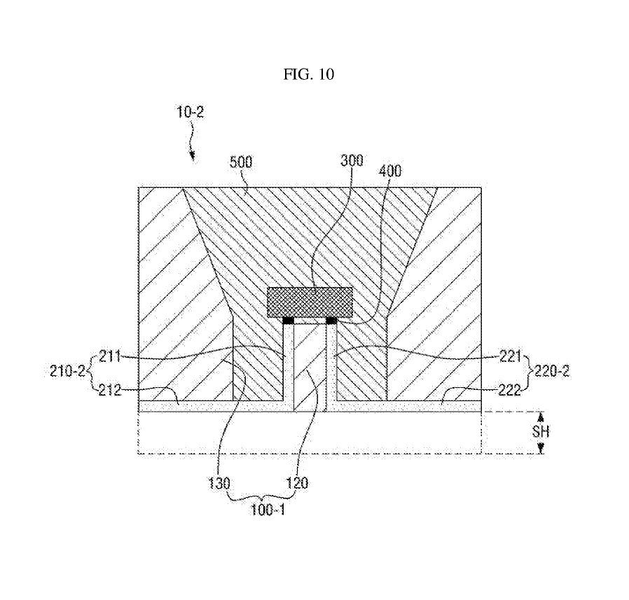

FIG. 10 is a view illustrating another exemplary embodiment of the light emitting device package illustrated in FIG. 2. In the illustrated exemplary embodiment, a light emitting device package 10-2 includes a body 100-1, a first electrode 210-2, and a second electrode 220-2 having different structures from those of the light emitting device package 10 illustrated in FIG. 2. Other configurations are the same as those as described above with reference to FIGS. 1 to 8, and the duplicate explanation thereof will be omitted for convenience.

Unlike the body as illustrated in FIG. 2, in the illustrated exemplary embodiment, the body 100-1 included in the light emitting device package 10-2 may include a support portion 120 and a side portion 130 only. That is, unlike the body 100 illustrated in FIG. 2, the body 100-1 may not be provided with a base portion 110 in FIG. 2.

Further, unlike those illustrated in FIG. 2, in the illustrated exemplary embodiment, the first electrode 210-2 and the second electrode 220-2 included in the light emitting device package 10-2 may respectively include a first projection portion 211 and a first connection portion 212, and a second projection portion 221 and a second connection portion 222 only. That is, unlike the first electrode 210 and the second electrode 220 illustrated in FIG. 2, a first contact portion 213 and a second contact portion 223 illustrated in FIG. 2 may not be separately provided. The first connection portion 212 and the second connection portion 222 are exposed as a lower part of the light emitting device package 10-2 to serve as the contact portions.

According to the illustrated exemplary embodiment, the body 100-1 is not provided with a separate base portion 110 in FIG. 2, and thus the whole thickness of the light emitting device package 10-2 can be reduced by the thickness SH that is occupied by the base portion 110 in FIG. 2.

FIG. 11 is a cross-sectional view illustrating a light emitting device package array according to an exemplary embodiment of the invention, and FIG. 12 is a cross-sectional view illustrating a light emitting device package array according to another exemplary embodiment of the invention.

Referring to FIG. 11, a light emitting device package array 1 according to an exemplary embodiment of the invention may include a plurality of light emitting device packages 10, a circuit board 90, and a contact terminal portion 91.

In an exemplary embodiment, the circuit board 90 may be a printed circuit board (“PCB”), and may include an organic resin material including epoxy, triazine, silicon, and polyimide, and other organic resin materials, for example. In an exemplary embodiment, the circuit board 90 may be a metal core printed circuit board (“MCPCB”).

The terminal portion 91 is a portion on which the light emitting device package 10 is mounted, and may be electrically connected to the first electrode 210 and the second electrode 220 of the light emitting device package 10 as illustrated in FIG. 1. In an exemplary embodiment, the terminal portion 91 may be a circuit pattern that includes a metal material having superior electrical conductivity and thermal conductivity, for example, gold (Au), silver (Ag), or copper (Cu), and a plurality of terminal portions 91 may be arranged on the circuit board 90.

The explanation of the light emitting device package 10 is the same as that as described above with reference to FIGS. 1 to 8, and thus will be omitted.

According to the light emitting device package array 1 in the illustrated exemplary embodiment in FIG. 11, the terminal portions 91 are positioned on the upper portion of the circuit board 90, and the light emitting device packages 10 are respectively mounted on the terminal portions 91.

Referring to FIG. 12, a light emitting device package array 2 according to another exemplary embodiment of the invention may include a plurality of light emitting device packages 10, a circuit board 90, and a contact terminal portion 92, and a groove 93 may be defined in the circuit board 90.

Unlike those as described above with reference to FIG. 11, in the illustrated exemplary embodiment, a plurality of grooves 93 is defined in the circuit board 90 of the light emitting device package array 2. The terminal portion 91 may be arranged in the groove 93, and a part of the light emitting device package 10 may be arranged in the groove 93 to contact the terminal portion 91. That is, according to the light emitting device package array 2 in the illustrated exemplary embodiment, the grooves 93, in which the light emitting device packages 10 are mounted, are defined in the circuit board 90, and thus the distance measured from the lower surface of the circuit board 90 to the uppermost portion of the light emitting device package 10, that is, the whole height of the light emitting device package array 2, can be decreased. In the illustrated exemplary embodiment of FIGS. 11 and 12, light emitting device package arrays 1 and 2 include the light emitting device packages 10 having the structure as illustrated in FIG. 2. However, this is merely exemplary, and the light emitting device package arrays 1 and 2 may include the light emitting device package 10-1 as illustrated in FIG. 9 and the light emitting device package 10-2 as illustrated in FIG. 10.

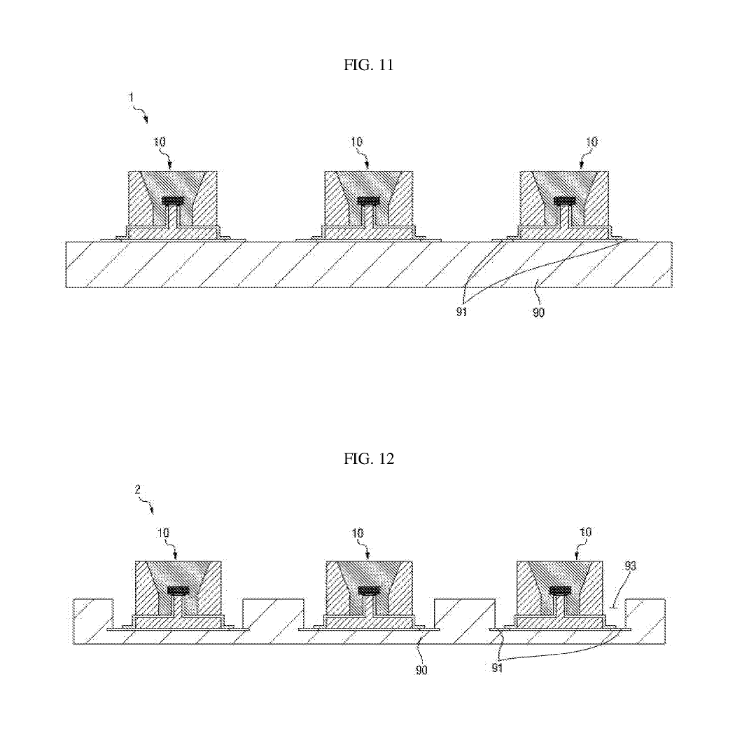

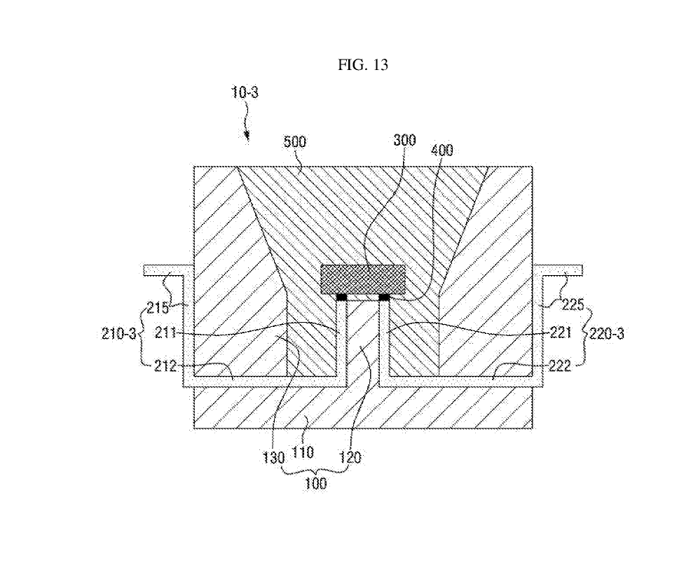

FIG. 13 is a cross-sectional view illustrating another exemplary embodiment of the light emitting device package illustrated in FIG. 2.

In the illustrated exemplary embodiment, a light emitting device package 10-3 includes a first electrode 210-3 and a second electrode 220-3 having different structures from those of the light emitting device package 10 illustrated in FIG. 2. Other configurations are the same as those as described above with reference to FIGS. 1 to 8, and the duplicate explanation thereof will be omitted for convenience.

In the illustrated exemplary embodiment, end parts of the first electrode 210-3 and the second electrode 220-3 included in the light emitting device package 10-3 may be positioned on an upper side of the base portion 110. That is, a first contact portion 215 of the first electrode 210-3 may extend along an outer surface of a side portion 130 and may project to an outside of a body 100. In the same manner, a second contact portion 225 may extend along the outer surface of the side portion 130 and may project to the outside of the body 100.

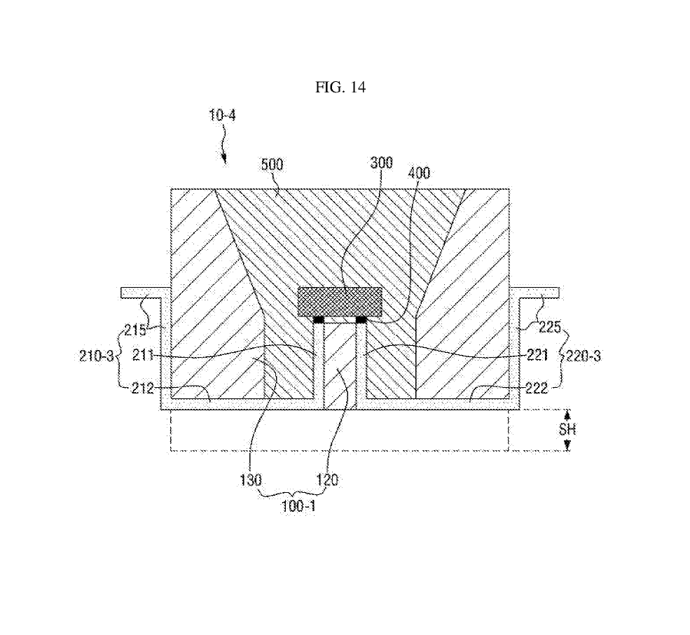

FIG. 14 is a cross-sectional view illustrating another exemplary embodiment of the light emitting device package illustrated in FIG. 13.

Unlike the exemplary embodiment as illustrated in FIG. 13, the body 100-1 included in the light emitting device package 10-4 may include a support portion 120 and a side portion 130 only. That is, unlike the body 10-3 illustrated in FIG. 13, the body 100-1 may not be provided with a base portion 110 in FIG. 13.

According to the illustrated exemplary embodiment, the body 100-1 is not provided with a separate base portion 110 in FIG. 13, and thus the whole thickness of the light emitting device package 10-4 can be reduced by the thickness SH that is occupied by the base portion 110 in FIG. 13.

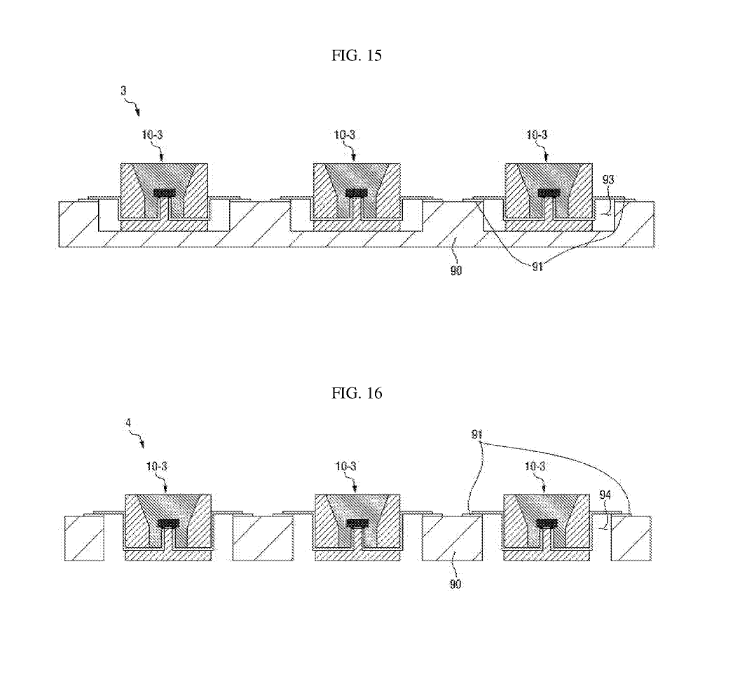

FIGS. 15 and 16 are cross-sectional views illustrating light emitting device package arrays according to another exemplary embodiment of the invention.

Referring to FIG. 15, a light emitting device package array 3 according to another exemplary embodiment of the invention may include a plurality of light emitting device packages 10-3, a circuit board 90, and a contact terminal portion 91, and a groove 93 may be defined in the circuit board 90.

The explanation of the light emitting device package 10-3 is the same as that as described above with reference to FIG. 13, and thus will be omitted.

A plurality of grooves 93 may be defined in the circuit board 90, and the terminal portion 91 may be arranged on an upper part of the circuit board 90 that is adjacent to the groove 93. Further, a part of the light emitting device package 10-3 may be arranged in the groove 93 to contact the terminal portion 91. The explanation of the circuit board 90 and the terminal portion 91 is the same as that as described above with reference to FIG. 11, and thus will be omitted.

Referring to FIG. 16, a light emitting device package array 4 according to another exemplary embodiment of the invention may include a plurality of light emitting device packages 10-3, a circuit board 90, a contact terminal portion 91, and a hole 94.

A plurality of holes 94 that penetrate the circuit board 90 are defined in the circuit board 90, and the terminal portion 91 may be arranged on an upper part of the circuit board 90 that is adjacent to the hole 94. Further, a part of the light emitting device package 10-3 may be arranged in the hole 94 to contact the terminal portion 91. In the illustrated exemplary embodiment, a lower surface of the light emitting device package 10-3 is positioned on the same horizontal plane as a lower surface of the circuit board 90. However, this is merely exemplary, and the part of the light emitting device package 10-3 may project downward to be lower than the lower surface of the circuit board 90. In this case, the thickness that is occupied by the light emitting device package 10-3 in the light emitting device package array 4 can be further reduced, and thus a thinner light emitting device package array 4 can be provided.

Referring to FIGS. 15 and 16, it is described that the light emitting device package arrays 3 and 4 include the light emitting device package 10-3 having the structure as illustrated in FIG. 13. However, this is merely exemplary, and the light emitting device packages 3 and 4 may include light emitting device package 10-4 as illustrated in FIG. 14.

FIG. 17 is a cross-sectional view of a light emitting device package according to another exemplary embodiment of the invention.

Referring to FIG. 17, in the illustrated exemplary embodiment, a light emitting device package 20 may include a transparent substrate 1000, a first electrode 2100 and a second electrode 2200 positioned on one surface of the transparent substrate 1000, a light emitting device 3000, wires 4100 and 4200, a wavelength conversion portion 5100, and a body 6000.

In an exemplary embodiment, the transparent substrate 1000 may be an insulating substrate having light permeability. In an exemplary embodiment, the transparent substrate 1000 may be a light-permeable, insulating, or conductive substrate. In an exemplary embodiment, the transparent substrate 1000 may include at least one of sapphire (Al₂O₃), SiC, Si, GaAs, GaN, ZnO, Si, GaP, InP, Ge, Ga2O3, or may include a plastic material.

The first electrode 2100 and the second electrode 2200 may be arranged on one surface of the transparent substrate 1000 to be spaced apart from each other. In an exemplary embodiment, the first electrode 2100 and the second electrode 2200 may include a light-permeable material having electrical conductivity, and may have a single-layer or multilayer structure. In an exemplary embodiment, the material of the first electrode 2100 and the second electrode 2200 may include at least one of indium tin oxide (“ITO”), indium zinc oxide (“IZO”), indium Zinc tin oxide (“IZTO”), indium aluminum zinc oxide (“IAZO”), indium gallium zinc oxide (“IGZO”), indium gallium tin oxide (“IGTO”), aluminum zinc oxide (“AZO”), antimony tin oxide (“ATO”), gallium zinc oxide (“GZO”), but is not limited thereto.

The light emitting device 3000 may be arranged between the first electrode 2100 and the second electrode 2200 positioned on one surface of the transparent substrate 1000. The light emitting device 3000 may have so-called volume emitting characteristics in which light is emitted from the whole surface of the light emitting device 3000. In an exemplary embodiment, the light emitting device 3000 may be an LED, but is not limited thereto. In an exemplary embodiment, the light emitting device 3000 may be an LED that emits color light, such as a red LED, a green LED, or a blue LED, or may be a white LED. Further, the light emitting device 3000 may be an LED that emits UV light. In an exemplary embodiment, the light emitting device 3000 may be attached to the transparent substrate 1000 through the medium of an adhesive member (not illustrated in the drawing), and the adhesive member may include a light-permeable material.

The light emitting device 3000 may be electrically connected to the first electrode 2100 and the second electrode 2200 through the wires 4100 and 4200. That is, the light emitting device 3000 may be electrically connected to the first electrode 2100 and the second electrode 2200 by a wire bonding method.

The body 6000 in which a cavity CA2 is defined may be arranged on one surface of the transparent substrate 1000. The body 6000 may include a base portion 6100 and a side portion 6200, and an inner surface 6101 of the base portion 6100 and an inner surface 6102 of the side portion 6200 may provide the cavity CA2. The body 6000 may be arranged on one surface of the transparent substrate 1000. More specifically, the inner surface 6101 of the body 6000 may be arranged to face the one surface of the transparent substrate 1000, and thus the body 6000 can cover the light emitting device 3000 and the wires 4100 and 4200. Further, the body 6000 may cover a part of the first electrode 2100 and a part of the second electrode 2200. That is, a portion of the first electrode 2100 and the second electrode 2200 may not be covered by the body 6000 and is exposed to an outside of the body 6000, and the corresponding portion of the first electrode 2100 and the second electrode 2200 may include a contact portion that contacts an external circuit (e.g., contact terminal of the circuit board).

In an exemplary embodiment, the body 6000 may include polymer including PPA and LCP, which are used as general package materials, for example. Further, the body 6000 may include white molding compound having opacity or high light reflectivity, and in this case, the inner surfaces 6101 and 6102 of the body 6000 may function as reflective surfaces. The white molding compound reflects light that is emitted from the light emitting device 3000, and increases the quantity of light that is emitted upward. In an exemplary embodiment, the white molding compound may include high heat resistant thermosetting resin or silicon resin, for example. In an exemplary embodiment, the thermoplastic resin may further include a white pigment, a filler, a curing agent, a release agent, an antioxidant, and an adhesive force improvement agent. In an exemplary embodiment, the body 6000 may include a metal material having superior light reflectivity, for example, at least one selected from metals of Al, Ag, Ru, Pd, Rh, Pt, and Ir, and alloys including two or more of the metals, but is not limited thereto.

The cavity CA2 may define a light emission region. More specifically, the light emitted from the light emitting device 3000 is provided to an outside of the light emitting device package 20 through an open part of the cavity CA2 or a part where the base portion 6100 and the side portion 6200 are not arranged. In an exemplary embodiment, the width of the light emission region or the width LW2 of the open part of the cavity CA2 may be about 200 μm to about 500 μm. Further, in an exemplary embodiment, the width LW2 of the open part of the cavity CA2 may be about 200 μm to about 400 μm.

At least one side surface of the cavity CA2, that is, the inner surface 6102 of the side portion 6200 may be inclined at a predetermined angle α1 with reference to a vertical direction in a cross section. In an exemplary embodiment, the predetermined angle α1 may be larger than 0 degree and equal to or smaller than 90 degrees, but is not limited thereto. In the illustrated exemplary embodiment, the width of the cavity CA2 may be increased as being closer to the transparent substrate 1000, and the cross section thereof may be in a reverse tapered shape, but is not limited thereto.

The wavelength conversion portion 5100 may be arranged on the other surface of the transparent substrate 1000. In an exemplary embodiment, the wavelength conversion portion 5100 is a portion that converts the light emitted from the light emitting device 3000 into light having a different wavelength, and may include phosphors, for example. In the exemplary embodiment, the phosphors may include at least one of a red phosphor, a green phosphor, a blue phosphor, and a yellow phosphor, for example. In the exemplary embodiment, the phosphors may be selectively including YAG, TAG, silicate, nitride, or oxynitride series material, for example, but is not limited thereto. In an exemplary embodiment, the wavelength conversion portion 5100 may be in a phosphor film shape, but is not limited thereto. In an exemplary embodiment, the wavelength conversion portion 5100 may be provided by spreading resin that includes the phosphors on the other surface of the transparent substrate 1000.

In an exemplary embodiment, air may exist in the cavity CA2, or an encapsulation portion may be provided through filling of light-permeable resin. In an exemplary embodiment, the light-permeable resin may include, for example, epoxy, silicon, urethane, oxetane, or acryl, but is not limited thereto.

According to the light emitting device package 20 in the illustrated exemplary embodiment, the light emitting device 3000 is arranged adjacent to the light emission region (or the open portion of the cavity CA2). Accordingly, a path of light that is emitted from the light emitting device 3000 to an outside can be shortened, and a light loss can be reduced to improve the light efficiency. Further, the light that is emitted from the light emitting device 3000 to the inside of the cavity CA2 can be guided to the light emission region by the inner surfaces 6100 and 6200 of the body 6000, and thus the light efficiency can be further improved.

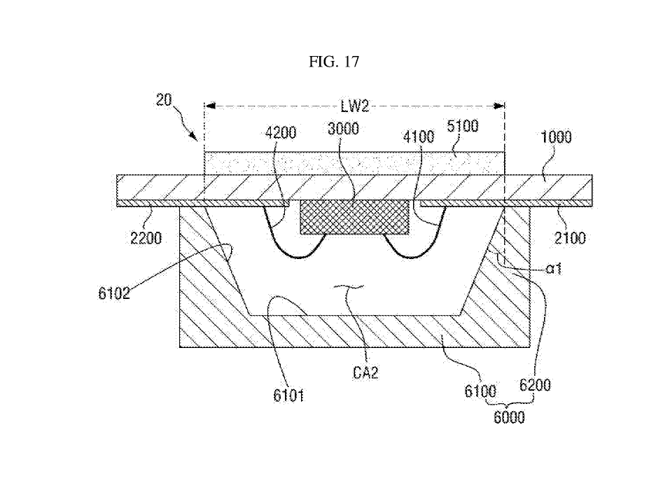

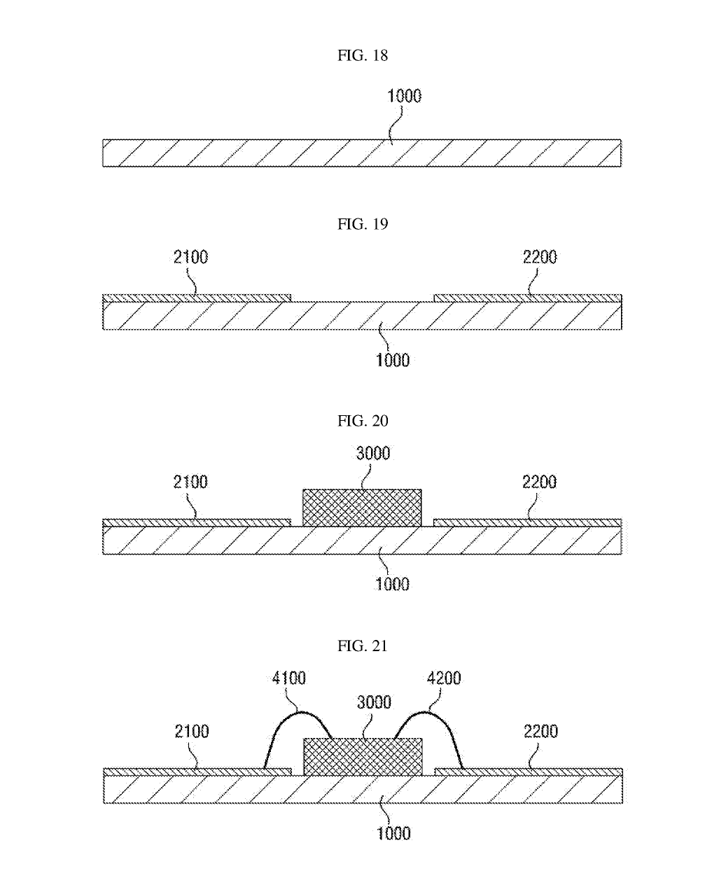

FIGS. 18 to 23 are cross-sectional views of processing operations explaining a method for manufacturing a light emitting device package according to another exemplary embodiment of the invention.

Referring to FIGS. 18 to 23, a transparent substrate 1000 is first provided as illustrated in FIG. 18, and a first electrode 2100 and a second electrode 2200, which are spaced apart from each other, are disposed on one surface of the transparent substrate 1000 as illustrated in FIG. 19. The first electrode 2100 and the second electrode 2200 may include a light-permeable material having electrical conductivity, and may have a single-layer or multilayer structure.

Next, as illustrated in FIG. 20, a light emitting device 3000 is arranged on a gap portion between the first electrode 2100 and the second electrode 2200 positioned on one surface of the transparent substrate 1000. In an exemplary embodiment, the light emitting device 3000 may be attached to the transparent substrate 1000 through the medium of an adhesive member (not illustrated), and the adhesive member may include a light-permeable material.

Thereafter, as illustrated in FIG. 21, the first electrode 2100, the second electrode 2200, and the light emitting device 3000 are electrically connected to each other using the wires 4100 and 4200.

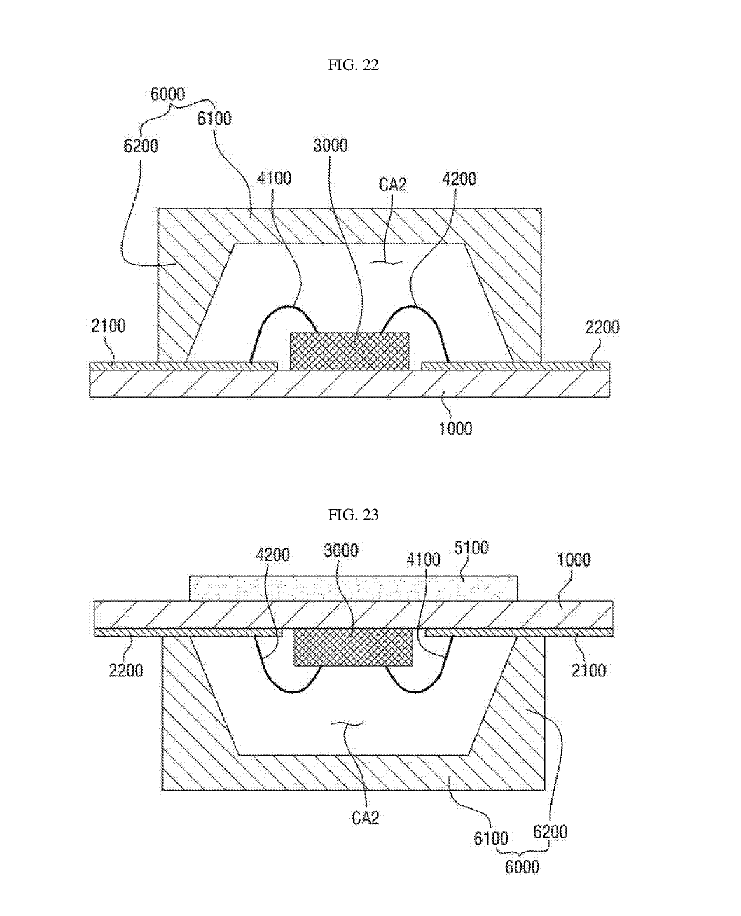

Further, as illustrated in FIG. 22, the body 6000, in which the cavity CA2 is defined by a base portion 6100 and a side portion 6200 of the body 6000, is arranged on one surface of the transparent substrate 1000. In the illustrated exemplary embodiment, the body 6000 may be arranged to cover the light emitting device 3000, the wires 4100 and 4200, a part of the first electrode 2100, and a part of the second electrode 2200, and may contact the first electrode 2100 and the second electrode 2200. In an exemplary embodiment, the body 6000 may be fixed onto the first electrode 2100 and the second electrode 2200 through the medium of a separate adhesive member (not illustrated in the drawing), but is not limited thereto.

Although not illustrated in the drawing, in the case where a separate encapsulation portion is provided in the cavity CA2, a process of filling light-permeable resin in the cavity CAS2 may be added.

Thereafter, as illustrated in FIG. 23, a wavelength conversion portion 5100 is disposed on the other surface of the transparent substrate 1000. The wavelength conversion portion 5100 is a portion that includes phosphors, and the wavelength conversion portion 5100 may be provided by various methods. In an exemplary embodiment, in the case where the wavelength conversion portion 5100 is in a film shape, the wavelength conversion portion 5100 may be attached to the other surface of the transparent substrate 1000 through the medium of a separate adhesive member. In an exemplary embodiment, in the case where the wavelength conversion portion 5100 is in a resin shape including phosphors, the wavelength conversion portion 5100 may be provided by spreading resin that includes phosphors on the other surface of the transparent substrate 1000 and curing the spread resin.

The process of providing the wavelength conversion portion 5100 on the other surface of the transparent substrate 1000 may be performed in another stage. In an exemplary embodiment, the process of providing the wavelength conversion portion 5000 may be performed after the process of providing the transparent substrate 1000 as illustrated in FIG. 18, and there is not limit in the order in which the process of providing the wavelength conversion portion 5000 and the processes of providing other configurations are performed.

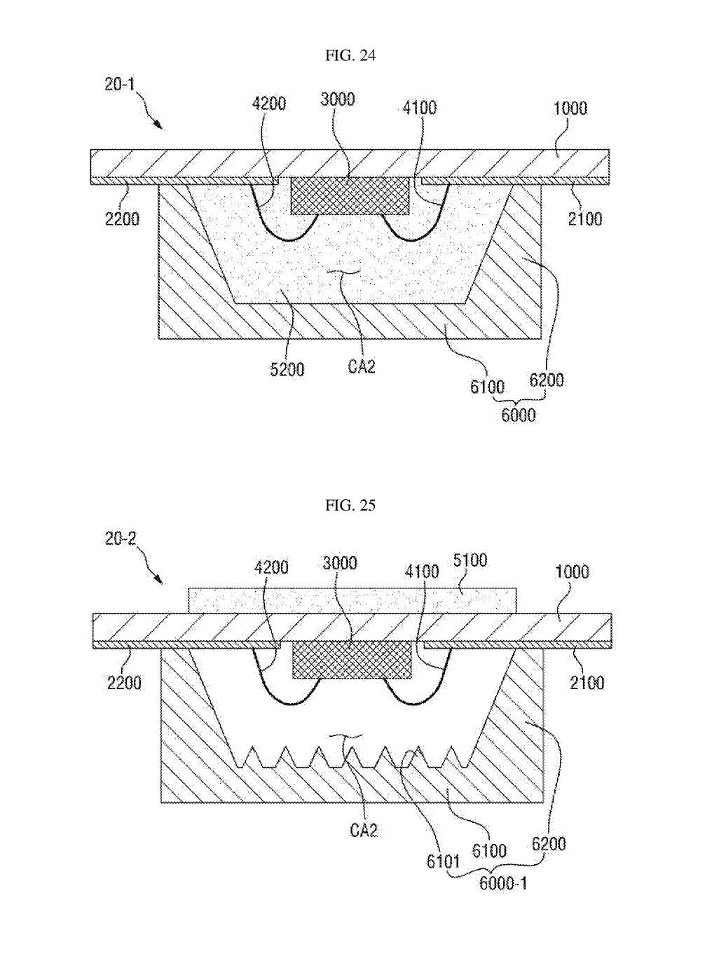

FIG. 24 is a cross-sectional view illustrating an exemplary embodiment of the light emitting device package illustrated in FIG. 17.

Referring to FIG. 24, in the illustrated exemplary embodiment, a light emitting device package 20-1 is different from the light emitting device package 20 as illustrated in FIG. 17 in that an encapsulation portion 5200 that includes a wavelength conversion material is provided in the cavity CA2. Other configurations are the same as those as described above with reference to FIG. 17, and the explanation of the duplicate contents will be omitted for convenience.

The encapsulation portion 5200 that covers the light emitting device 3000 and the wires 4100 and 4200 is positioned in the cavity CA2 of the light emitting device package 20-1. The encapsulation portion 5200 may fill in the cavity CA2 to encapsulate the light emitting device 3000. In an exemplary embodiment, the encapsulation portion 5200 may include a light-permeable material, for example, light-permeable resin, such as epoxy, silicon, urethane, oxetane, or acryl. In an exemplary embodiment, the encapsulation portion 5200 may further include a wavelength conversion material that converts a part of the light emitted from the light emitting device 3000 into light having a different wavelength, for example, phosphors, through excitation of the part of the light. In an exemplary embodiment, the phosphors may include at least one of a red phosphor, a green phosphor, and a yellow phosphor, and may include at least one of YAG, TAG, silicate, nitride, and oxynitride series material, but is not limited thereto.

In the illustrated exemplary embodiment, the light emitting device package 20-1 may not include the separate wavelength conversion portion 5100 of FIG. 17. However, the invention is not limited thereto, and although not illustrated in the drawing, it is also possible to additionally arrange the wavelength conversion portion 5100 of FIG. 17 on the other surface of the transparent substrate 1000.

FIG. 25 is a cross-sectional view illustrating another exemplary embodiment of the light emitting device package illustrated in FIG. 17. In the illustrated exemplary embodiment, the light emitting device package 20-2 includes a body 6000-1 having a different structure from that of the light emitting device package 20 as illustrated in FIG. 17.

Referring to FIG. 25, a concavo-convex pattern 6101 may be provided inside the body 6000-1 of the light emitting device package 20-2. In an exemplary embodiment, the concavo-convex pattern 6101 may be a negative pattern or a positive pattern, and the cross section thereof may have various shapes, such as a triangle, a rectangle, a semi-circle, and a semi-ellipse. In an exemplary embodiment, the planar shape of the concavo-convex pattern 6101 may be a circle, a polygon, or the like. As the concavo-convex pattern 6101 is provided, the light that is directed to the inner surface of the base portion 6100 of the body 6000-1 can be guided to the other side of the transparent substrate 1000 more effectively, and thus the light efficiency can be improved.

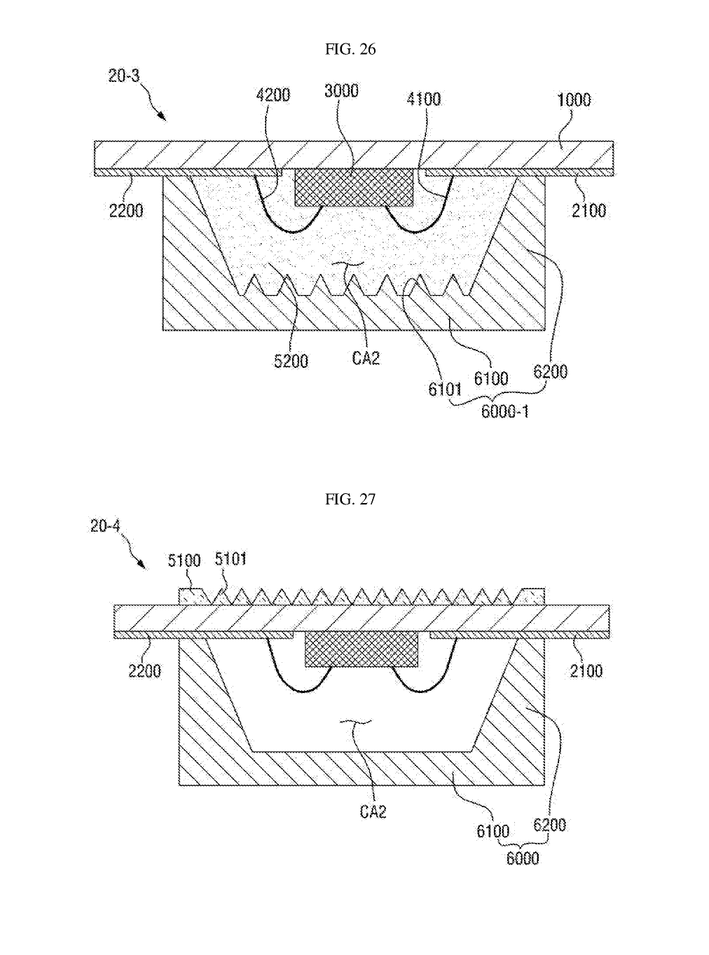

FIG. 26 is a cross-sectional view illustrating another exemplary embodiment of the light emitting device package illustrated in FIG. 17. In the illustrated exemplary embodiment, the light emitting device package 20-3 is different from the light emitting device package 20 as illustrated in FIG. 17 on the points that the wavelength conversion portion 5100 of FIG. 17 is not provided on the upper part of the transparent substrate 1000 and an encapsulation portion 5200 that is provided in the cavity CA2 is provided. Other configurations are the same as those as described above.

Referring to FIG. 26, in the illustrated exemplary embodiment, the light emitting device package 20-3 may have the structure of the body 6000-1 as illustrated in FIG. 25, and the encapsulation portion 5200 may be positioned in the cavity CA2 to cover the light emitting device 3000 and the wires 4100 and 4200. The encapsulation portion 5200 may include a light-permeable material, and may further include a wavelength conversion material that converts a part of the light emitted from the light emitting device 3000 into light having a different wavelength, for example, phosphors.

FIG. 27 is a cross-sectional view illustrating another exemplary embodiment of the light emitting device package illustrated in FIG. 17. In the illustrated exemplary embodiment, the light emitting device package 20-4 is different from the light emitting device package 20 as illustrated in FIG. 17 in that a concavo-convex pattern 5101 is additionally disposed on the wavelength conversion portion 5100. Other configurations are the same as those of the light emitting device package 20 of FIG. 17.

A concavo-convex pattern 5101 may be disposed on the wavelength conversion portion 5100. The concavo-convex pattern 5101 may be a negative pattern or a positive pattern, and the shape thereof is not limited. According to the illustrated exemplary embodiment, since the concavo-convex pattern 5101 is additionally provided, the threshold angle of the light that is incident to the wavelength conversion portion 5100 can be changed, and thus the total reflection rate of the incident light can be reduced to improve the light efficiency.

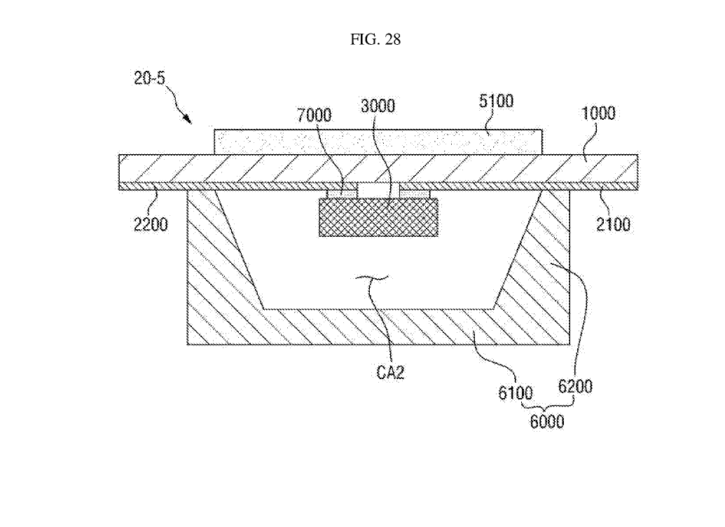

FIG. 28 is a cross-sectional view illustrating another exemplary embodiment of the light emitting device package illustrated in FIG. 17. In the illustrated exemplary embodiment, the light emitting device package 20-5 is different from the light emitting device package 20 as illustrated in FIG. 17 in that the light emitting device 3000, the first electrode 2100, and the second electrode 2200 are electrically connected through the medium of a bump 7000. Other configurations are the same as those of the light emitting device package 20 of FIG. 17.

According to the light emitting device package 20-5 according to the illustrated exemplary embodiment, a part of the light emitting device 3000 may be arranged to overlap the first electrode 2100 and the second electrode 2200, and the light emitting device 3000 is electrically connected to the first electrode 2100 and the second electrode 2200 through the medium of the bump 7000 rather than the wires 4100 and 4200 of FIG. 17. That is, the light emitting device 3000 may be flip-chip-bonded to the first electrode 2100 and the second electrode 2200.

According to the illustrated exemplary embodiment, since the wires 4100 and 4200 are not used, the width of the light emitting device package 20-5 can be further reduced, and the light emitting device 3000 having high efficiency with respect to the same area can be arranged. Further, since the light reflection that is caused by the wires can be prevented, the light efficiency can be improved.

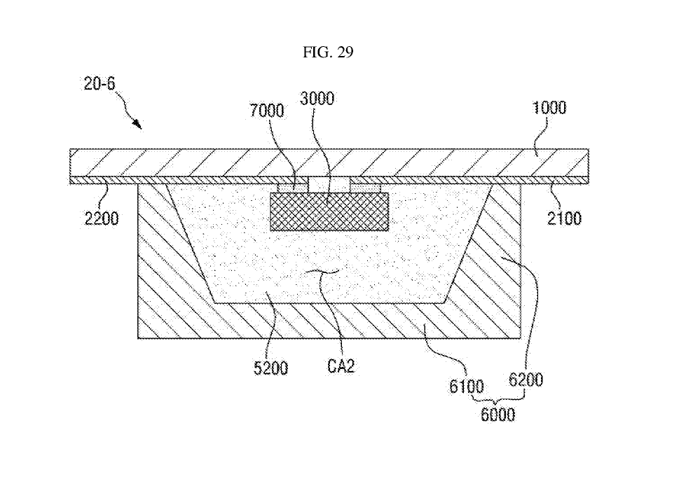

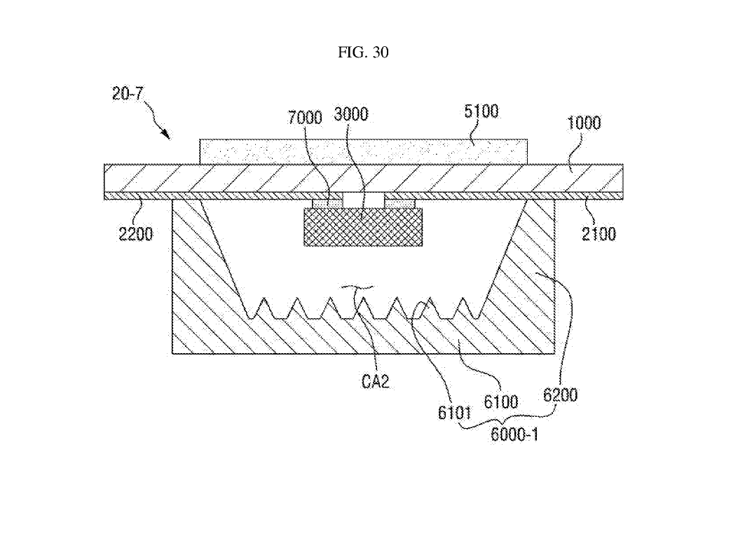

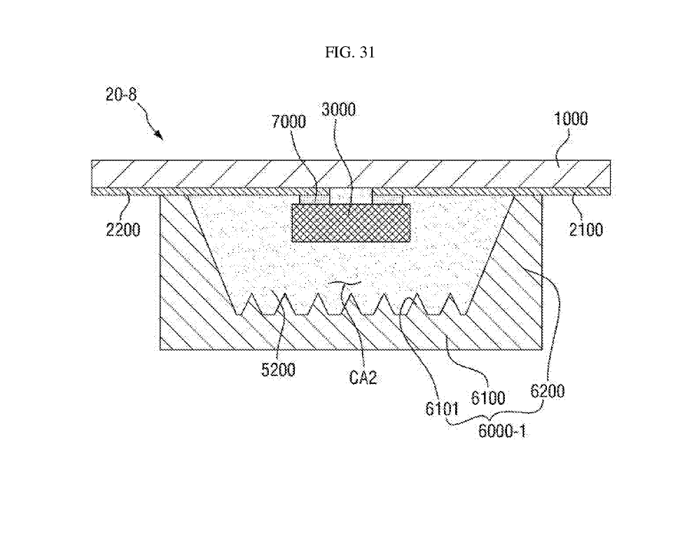

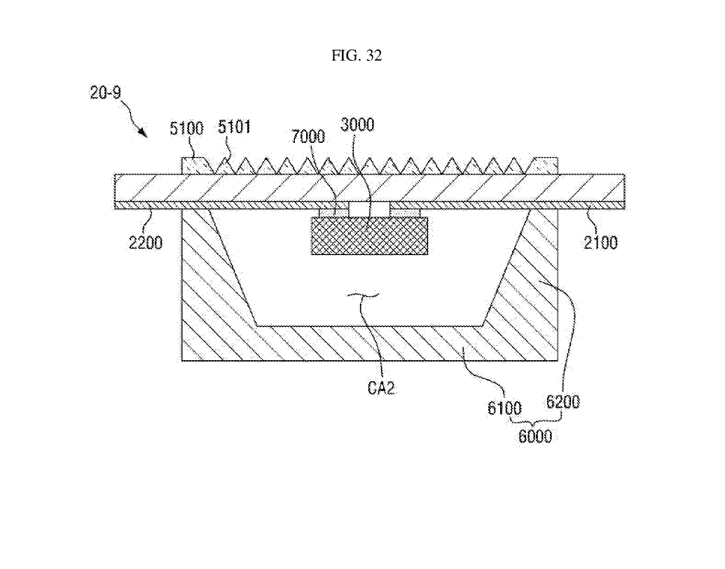

FIGS. 29 to 32 are views illustrating other exemplary embodiments of the light emitting device package illustrated in FIG. 17. More specifically, the light emitting device packages 20-6, 20-7, 20-8, and 20-9 illustrated in FIGS. 29 to 32 are different from the light emitting device packages 20-1, 20-2, 20-3, and 20-4 illustrated in FIGS. 24 to 27, respectively, in that the light emitting device 3000, the first electrode 2100, and the second electrode 2200 are electrically connected through the medium of the bump 7000.

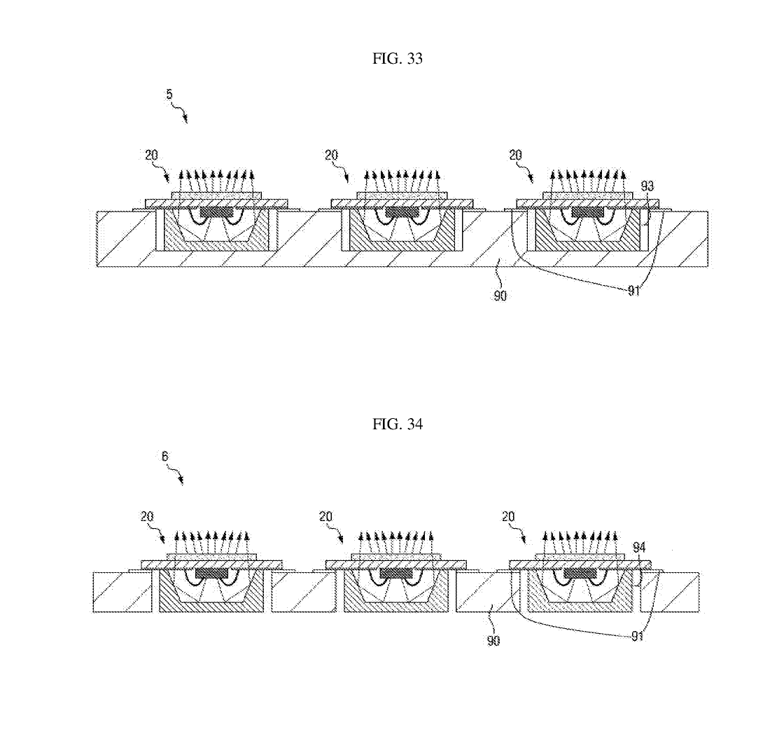

FIGS. 33 and 34 are cross-sectional views illustrating light emitting device package arrays according to other embodiments of the invention.

Referring to FIG. 33, a light emitting device package array 5 according to another exemplary embodiment of the invention may include a plurality of light emitting device packages 20, a circuit board 90, and a contact terminal portion 91. A groove 93 may be defined in the light emitting device package array 5.

The explanation of the light emitting device package 20 is the same as that as described above with reference to FIG. 17, and thus will be omitted.

A plurality of grooves 93 may be defined in the circuit board 90, and the terminal portion 91 may be arranged on an upper part of the circuit board 90 that is adjacent to the grooves 93. Further, a part of the light emitting device package 20 may be arranged in the groove 93 to contact the terminal portion 91. The explanation of the circuit board 90 and the terminal portion 91 is the same as that as described above with reference to FIG. 15, and thus will be omitted.

Referring to FIG. 34, a light emitting device package array 6 according to another exemplary embodiment of the invention may include a plurality of light emitting device packages 20, a circuit board 90, and a contact terminal portion 91, and a hole 94 may be defined in the circuit board 90.

A plurality of holes 94 that penetrate the circuit board 90 may be disposed on the circuit board 90, and the terminal portion 91 may be arranged on an upper part of the circuit board 90 that is adjacent to the holes 94. Further, a part of the light emitting device package 20 may be arranged in the hole 94 to contact the terminal portion 91. In the illustrated exemplary embodiment, a lower surface of the light emitting device package 20 is positioned on the same horizontal plane as a lower surface of the circuit board 90. However, this is merely exemplary, and the part of the light emitting device package 20 may project downward to be lower than the lower surface of the circuit board 90. In this case, the thickness that is occupied by the light emitting device package 20 in the light emitting device package array 6 can be further reduced, and thus a thinner light emitting device package array 6 can be provided.

In the illustrated exemplary embodiment of FIGS. 33 and 34, the light emitting device package arrays 5 and 6 include the light emitting device packages 20 having the structure as illustrated in FIG. 17. However, this is merely exemplary, and the light emitting device package arrays 5 and 6 may include at least one of the light emitting device packages 20-1, 20-2, 20-3, 20-4, 20-5, 20-6, 20-7, 20-8, and 20-9 as illustrated in FIGS. 24 to 32, respectively.

Although preferred embodiments of the invention have been described for illustrative purposes, those skilled in the art will appreciate that various modifications, additions and substitutions are possible, without departing from the scope and spirit of the invention as disclosed in the accompanying claims.

1. A light emitting device package comprising:
a transparent substrate;
a first electrode positioned on one surface of the transparent substrate;
a second electrode positioned on the one surface of the transparent substrate and spaced apart from the first electrode;
a light emitting device positioned on the one surface of the transparent substrate and electrically connected to the first electrode and the second electrode; and
a body positioned on the one surface of the transparent substrate and having a cavity provided therein,
wherein the body covers the light emitting device, at least a part of the first electrode, and at least a part of the second electrode.

2. The light emitting device package of claim 1, further comprising an encapsulation portion filling in the cavity and encapsulating the light emitting device.

3. The light emitting device package of claim 2, wherein the encapsulation portion includes a wavelength conversion material.

4. The light emitting device package of claim 1, further comprising a wavelength conversion portion positioned on the other surface of the transparent substrate which faces the one surface of the transparent substrate.

5. The light emitting device package of claim 4, wherein a concavo-convex pattern is provided on one surface of the wavelength conversion portion.

6. The light emitting device package of claim 1, wherein the first electrode and the second electrode include a light-permeable material.

7. The light emitting device package of claim 1, wherein the light emitting device is electrically connected to the first electrode and the second electrode through a wire or a bump.

8. The light emitting device package of claim 1, wherein at least one side surface of the cavity is inclined with respect to a vertical direction in a cross section.

9. The light emitting device package of claim 1, wherein a concavo-convex pattern is provided on an inner surface of the body which faces the light emitting device.
